(19) United States
(12) Patent Application Publication
(10) Pub. No.: US 2024/0162195 A1
(43) Pub. Date: May 16, 2024

(54) SEMICONDUCTOR PACKAGE AND METHOD OF MANUFACTURING THE SAME

(71) Applicant: Samsung Electronics Co., Ltd., Suwon-si (KR)

(72) Inventor: Yongjin Park, Suwon-si (KR)

(21) Appl. No.: 18/469,609

(22) Filed: Sep. 19, 2023

(30) Foreign Application Priority Data
Nov. 16, 2022 (KR) 10-2022-0153983

(51) Int. Cl. H01L 25/065; H01L 23/00; H01L 23/31; H10B 80/00

(52) U.S. Cl. CPC H01L 25/0657; H01L 23/3135; H01L 24/16; H01L 24/32; H01L 24/33; H01L 24/73; H10B 80/00; H01L 2224/16148; H01L 2224/32059; H01L 2224/32145; H01L 2224/3303; H01L 2224/73204; H01L 2225/06513; H01L 2225/06541; H01L 2924/1431; H01L 2924/1436

(57) ABSTRACT

A semiconductor package includes a first semiconductor chip including a support structure extending away from a top surface thereof, a second semiconductor chip stacked on the first semiconductor chip, having a horizontal width that is less than that of the first semiconductor chip, and having an edge horizontally spaced apart from that of the first semiconductor chip in a plan view, and an insulating adhesive layer between the first semiconductor chip and the second semiconductor chip that extends away from between the first semiconductor chip and the second semiconductor chip to cover the support structure. In a plan view, the support structure is horizontally spaced apart from the edge of the second semiconductor chip and an edge of the insulating adhesive layer.

### CROSS-REFERENCE TO RELATED APPLICATION

This application is based on and claims priority under 35 U.S.C. § 119 to Korean Patent Application No. 10-2022-0153983, filed on Nov. 16, 2022, in the Korean Intellectual Property Office, the disclosure of which is incorporated by reference herein in its entirety.

### BACKGROUND

The inventive concept relates to a semiconductor package and a method of manufacturing the same, and more particularly, to a semiconductor package including a plurality of vertically stacked semiconductor chips and a method of manufacturing the same.

In accordance with the rapid development of the electronics industry and demands of users, semiconductor packages mounted in electronic products are required to provide high performance and to include various functions. Therefore, a semiconductor package including a plurality of semiconductor chips is suggested.

In addition, in order to reduce a size of a semiconductor package including a plurality of semiconductor chips, a semiconductor package, in which a plurality of semiconductor chips are vertically stacked, is being developed.

### SUMMARY

The inventive concept relates to a semiconductor package including a plurality of vertically stacked semiconductor chips having structural reliability and a method of manufacturing the same.

In order to achieve the above object, according to the inventive concept, the following semiconductor package is provided.

According to an aspect of the inventive concept, there is provided a semiconductor package including a first semiconductor chip including a support structure extending away from upper major surface thereof, a second semiconductor chip on the first semiconductor chip, having a horizontal width less than that of the first semiconductor chip, and an edge horizontally spaced apart from an edge of the first semiconductor chip, and an insulating adhesive layer between the first semiconductor chip and the second semiconductor chip and extending horizontally outward from between the first semiconductor chip and the second semiconductor chip to cover the support structure. The support structure is horizontally spaced apart from an edge of the second semiconductor chip and the edge of the insulating adhesive layer.

According to another aspect of the inventive concept, there is provided a semiconductor package including a first semiconductor chip including a support structure extending away from a upper major surface thereof, a plurality of second semiconductor chips sequentially stacked on the first semiconductor chip, each having a horizontal width less than that of the first semiconductor chip, and each having an edge horizontally spaced apart from an edge of the first semiconductor chip in a plan view, and a plurality of insulating adhesive layers between the first semiconductor chip and the plurality of second semiconductor chips that extends away from between the first semiconductor chip and the plurality of second semiconductor chips. The plurality of insulating adhesive layers include a first insulating adhesive layer between a lowermost second semiconductor chip of the plurality of second semiconductor chips and the first semiconductor chip and at least one second insulating adhesive layer between the plurality of second semiconductor chips. The first insulating adhesive layer is on top and side surfaces of the support structure and extends horizontally further outward from between the lowermost second semiconductor chip of the plurality of second semiconductor chips and the first semiconductor chip than the support structure.

According to another aspect of the inventive concept, there is provided a semiconductor package including a buffer chip including a first substrate having a first active surface and an opposite first inactive surface, a plurality of first through electrodes extending onto the first inactive surface through at least a part of the first substrate, a first protective layer including a first lower protective layer, a first intermediate protective layer, and a first upper protective layer on the first inactive surface of the first substrate and on the plurality of first through electrodes, a support structure extending away from a top surface of the first upper protective layer and including the same material as the first upper protective layer, and a first wiring layer on the first active surface of the first substrate, a plurality of memory cell chips each having a width less than that of the buffer chip, the plurality of memory cell chips sequentially stacked on the buffer chip, and including a second substrate having a second active surface facing the first inactive surface of the first substrate and an opposite second inactive surface, a second protective layer on the second inactive surface of the second substrate, and a second wiring layer on the second active surface of the second substrate, a plurality of chip connection terminals between the buffer chip and the plurality of memory cell chips, a plurality of insulating adhesive layers between the buffer chip and the plurality of memory cell chips, on the plurality of chip connection terminals, wherein the plurality of insulating adhesive layers extend away from between the buffer chip and the plurality of memory cell chips, and a molding layer on the plurality of memory cell chips and the plurality of insulating adhesive layers on the buffer chip. The plurality of insulating adhesive layers include a first insulating adhesive layer between the lowermost memory cell chip of the plurality of memory cell chips and the buffer chip and at least one second insulating adhesive layer between the plurality of memory cell chips. The first insulating adhesive layer extends further outward from between the lowermost memory cell chip of the plurality of memory cell chips and the buffer chip than the support structure to cover top and side surfaces of the support structure. A vertical level of the top surface of the support structure is lower than that of a bottom surface of a lowermost memory cell chip of the plurality of memory cell chips.

According to another aspect of the inventive concept, there is provided a semiconductor package including preparing a first semiconductor chip including a first substrate having a first active surface and an opposite first inactive surface, a first protective layer on the first inactive surface of the first substrate, and a support structure extending away from a top surface of the first protective layer and attaching a second semiconductor chip, which includes a second substrate having a second active surface and a second inactive surface opposite to the second active surface and to a bottom surface of which an insulating adhesive layer is attached, onto the first semiconductor chip so that the second active surface faces the first inactive surface. The attaching of the second semiconductor chip onto the first semiconductor chip is performed by a thermal compression bonding process so that the insulating adhesive layer protrudes further outward from between the first semiconductor chip and the second semiconductor chip than the support structure to be on the support structure.

### BRIEF DESCRIPTION OF THE DRAWINGS

Embodiments will be more clearly understood from the following detailed description taken in conjunction with the accompanying drawings in which:

FIGS. 1A and 1B are a cross-sectional view and an enlarged cross-sectional view of a semiconductor package according to an embodiment;

FIGS. 2A to 2C are planar views illustrating planar configurations of some components of semiconductor packages according to embodiments;

FIGS. 3A and 3B are a cross-sectional view and an enlarged cross-sectional view of a semiconductor package according to an embodiment;

FIGS. 4A to 4H are cross-sectional views illustrating a method of manufacturing a first semiconductor chip included in a semiconductor package according to an embodiment; and

FIGS. 5A to 5D are cross-sectional views illustrating a method of manufacturing a semiconductor package according to an embodiment.

### DETAILED DESCRIPTION OF THE EMBODIMENTS

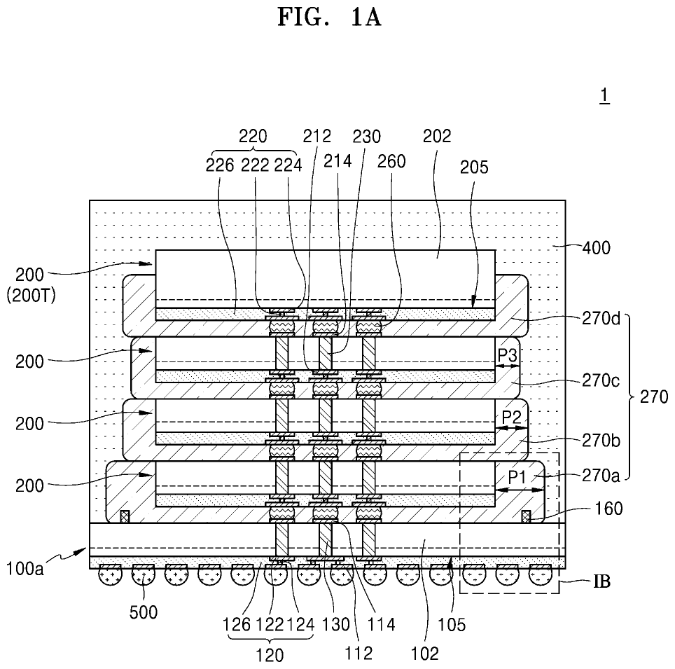

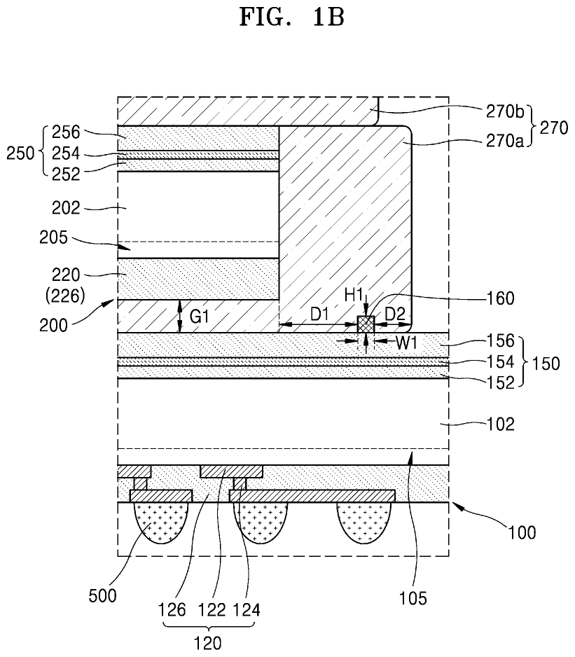

FIGS. 1A and 1B are respectively a cross-sectional view and an enlarged cross-sectional view of a semiconductor package 1 according to an embodiment.

Referring to FIGS. 1A and 1B, the semiconductor package 1 may include a first semiconductor chip 100, a plurality of second semiconductor chips 200 stacked on the first semiconductor chip 100, and a plurality of insulating adhesive layers 270 between the first semiconductor chip 100 and the plurality of second semiconductor chips 200.

In the current specification, the term “between the first semiconductor chip and the plurality of second semiconductor chips” means between each two of semiconductor chips including the first semiconductor chip and the plurality of second semiconductor chips. That is, in the current specification, the term “between the first semiconductor chip and the plurality of second semiconductor chips” means between the first semiconductor chip and the lowermost second semiconductor chip of the plurality of second semiconductor chips and between two adjacent second semiconductor chips among the plurality of second semiconductor chips.

It is illustrated in FIG. 1A that the semiconductor package 1 includes one first semiconductor chip 100 and four second semiconductor chips 200. However, the inventive concept is not limited thereto. For example, the semiconductor package 1 may include two or more second semiconductor chips 200. In some embodiments, the semiconductor package 1 may include a multiple of 4 second semiconductor chips 200. The plurality of second semiconductor chips 200 may be sequentially stacked on the first semiconductor chip 100 in a vertical direction.

A horizontal width of the first semiconductor chip 100 may be greater than that of each of the plurality of second semiconductor chips 200. An edge of each of the plurality of second semiconductor chips 200 may not be aligned in the vertical direction with an edge of the first semiconductor chip 100. For example, in a plan view, the edge of each of the plurality of second semiconductor chips 200 may be horizontally spaced apart from the edge of the first semiconductor chip 100. For example, the plurality of second semiconductor chips 200 may all overlap the first semiconductor chip 100 in the vertical direction, and the edge of each of the plurality of semiconductor chips 200 may be spaced apart from the edge of the first semiconductor chip 100 in the horizontal direction.

In some embodiments, the number of insulating adhesive layers 270 included in the semiconductor package 1 may be the same as the number of second semiconductor chips 200. For example, when the number of second semiconductor chips 200 included in the semiconductor package 1 is 4, the number of insulating adhesive layers 270 may be 4. For example, the plurality of insulating adhesive layers 270 may include a first insulating adhesive layer 270a, a second insulating adhesive layer 270b, a third insulating adhesive layer 270c, and a fourth insulating adhesive layer 270d. The first insulating adhesive layer 270a may be between the first semiconductor chip 100 and the lowermost second semiconductor chip 200 of the plurality of second semiconductor chips 200. Each of the second insulating adhesive layer 270b, the third insulating adhesive layer 270c, and the fourth insulating adhesive layer 270d may be between each two adjacent second semiconductor chips 200 among the four second semiconductor chips 200. The first insulating adhesive layer 270a, the second insulating adhesive layer 270b, the third insulating adhesive layer 270c, and the fourth insulating adhesive layer 270d may be sequentially arranged away from the first semiconductor chip 100.

The first semiconductor chip 100 includes a first substrate 102, a first wiring layer 120, a plurality of first through electrodes 130, and a first protective layer 150. A plurality of first front connection pads 112 may be attached to a bottom surface of the first semiconductor chip 100, and a plurality of first rear connection pads 114 may be attached to a top surface thereof. Each of the plurality of second semiconductor chips 200 includes a second substrate 202, a second wiring layer 220, a plurality of second through electrodes 230, and a second protective layer 250. A plurality of second front connection pads 212 may be attached to a bottom surface of each of the plurality of second semiconductor chips 200, and a plurality of second rear connection pads 214 may be attached to a top surface thereof.

Each of the plurality of first front connection pads 112, the plurality of first rear connection pads 114, the plurality of second front connection pads 212, and the plurality of second rear connection pads 214 may be formed by a plating process, such as electroplating or electroless plating. For example, each of the plurality of first front connection pads 112, the plurality of first rear connection pads 114, the plurality of second front connection pads 212, and the plurality of second rear connection pads 214 may include copper (Cu).

The first substrate 102 and the second substrate 202 may include silicon (Si). Alternatively, the first substrate 102 and the second substrate 202 may include a semiconductor element, such as germanium (Ge), or a compound semiconductor, such as silicon carbide (SiC), gallium arsenide (GaAs), indium arsenide (InAs), or indium phosphide (InP). Each of the first substrate 102 and the second substrate 202 may have an active surface and an inactive surface opposite to the active surface. The active surface and the inactive surface of the first substrate 102 may be referred to as a first active surface and a first inactive surface, and the active surface and the inactive surface of the second substrate 202 may be referred to as a second active surface and a second inactive surface. The second active surface of the second substrate 202 may face the first inactive surface of the first substrate 102.

Each of the first substrate 102 and the second substrate 202 may include various types of individual devices on the active surface. The plurality of individual devices may include various microelectronics devices, for example, a metal-oxide-semiconductor field effect transistor (MOSFET), such as a complementary metal-oxide-semiconductor (CMOS) transistor, an image sensor, such as a system large scale integration (LSI) sensor or a CMOS imaging sensor (CIS), a micro-electro-mechanical system (MEMS), an active element, and a passive element.

The first semiconductor chip 100 and each of the plurality of second semiconductor chips 200 may include a first semiconductor device 105 and a second semiconductor device 205 each configured by the plurality of individual devices. The first semiconductor device 105 may be on the first active surface of the first substrate 102, and the second semiconductor device 205 may be on the second active surface of the second substrate 202.

In the current specification, a front surface and a rear surface of a semiconductor chip are located on an active surface and an inactive surface of a substrate, and a top surface and a bottom surface of the semiconductor chip are located on an upper side and a lower side in a drawing.

The first semiconductor chip 100 and the plurality of second semiconductor chips 200 included in the semiconductor package 1 may be sequentially stacked in a face down form in which the first active surface and the plurality of second active surfaces face downward. For example, the first active surface of the first substrate 102 included in the first semiconductor chip 100 may face a side opposite to the plurality of second semiconductor chips 200, and the first inactive surface may face the plurality of second semiconductor chips 200. The second active surface of the second substrate 202 included in each of the plurality of second semiconductor chips 200 may face the first semiconductor chip 100, and the second inactive surface thereof may face a side opposite to the first semiconductor chip 100.

Each of the first semiconductor chip 100 and the plurality of second semiconductor chips 200 may include dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM).

In some embodiments, the first semiconductor chip 100 may not include a memory cell. The first semiconductor device 105 included in the first semiconductor chip 100 may include a serial-parallel conversion circuit, a test logic circuit, such as a design for test (DFT), a joint test action group (JTAG), or a memory built-in self-test (MBIST), and a signal interface circuit such as PHY. The second semiconductor device 205 included in each of the plurality of second semiconductor chips 200 may include a memory cell. For example, the first semiconductor chip 100 may be a buffer chip for controlling the plurality of second semiconductor chips 200.

In some embodiments, the first semiconductor chip 100 may be a buffer chip for controlling high bandwidth memory (HBM) DRAM, and the plurality of second semiconductor chips 200 may be memory cell chips having cells of the HBM DRAM controlled by the first semiconductor chip 100. The first semiconductor chip 100 may be referred to as a buffer chip or a master chip, and the plurality of second semiconductor chips 200 may be referred to as memory cell chips or slave chips. The first semiconductor chip 100 and the plurality of second semiconductor chips 200 stacked on the first semiconductor chip 100 may be referred to as an HBM DRAM device or an HBM DRAM chip.

The first wiring layer 120 may be on the first active surface of the first substrate 102, and the first protective layer 150 may be on the first inactive surface of the first substrate 102. The plurality of first front connection pads 112 may be on a bottom surface of the first wiring layer 120 and the plurality of first rear connection pads 114 may be on a top surface of the first protective layer 150. For example, the plurality of first rear connection pads 114 may be on the top surface or upper major surface of the first semiconductor chip 100, and the plurality of first front connection pads 112 may be on the bottom surface thereof. A plurality of package connection terminals 500 may be respectively attached to the plurality of first front connection pads 112. The plurality of package connection terminals 500 may function as external connection terminals of the semiconductor package 1. The plurality of package connection terminals 500 may connect the semiconductor package 1 to the outside. In some embodiments, the plurality of package connection terminals 500 may include bumps or solder balls.

The first wiring layer 120 may include a plurality of first wiring patterns 122, a plurality of first wiring vias 124, and a first interconnection insulating layer 126. The plurality of first wiring vias 124 may be connected to top surfaces and/or bottom surfaces of the plurality of first wiring patterns 122. In some embodiments, the plurality of first wiring patterns 122 may be spaced apart from one another at different vertical levels, and the plurality of first wiring vias 124 may connect the plurality of first wiring patterns 122 at different vertical levels to one another. The plurality of first wiring patterns 122 and the plurality of first wiring vias 124 may be electrically connected to the plurality of first through electrodes 130. The first interconnection insulating layer 126 may be on (e.g., to surround at least a portion of) the plurality of first wiring patterns 122 and the plurality of first wiring vias 124. In some embodiments, the plurality of first front connection pads 112 may be on a bottom surface of the first interconnection insulating layer 126 of the plurality of first wiring patterns 122.

The plurality of first through electrodes 130 may vertically pass through at least a part of the first substrate 102 to electrically connect the plurality of first front connection pads 112 to the plurality of first rear connection pads 114. The plurality of first through electrodes 130 may pass through at least a part of the first substrate 102 and the first protective layer 150. For example, the plurality of first front connection pads 112 may be electrically connected to the plurality of first rear connection pads 114 through the plurality of first through electrodes 130, the plurality of first wiring patterns 122, and the plurality of first wiring vias 124, respectively.

The second wiring layer 220 may be on the second active surface of the second substrate 202, and the second protective layer 250 may be on the second inactive surface of the second substrate 202. The plurality of second front connection pads 212 may be on a bottom surface of the second wiring layer 220, and the plurality of second rear connection pads 214 may be on a top surface of the second protective layer 250. For example, the plurality of second rear connection pads 214 may be on the top surface of each of the plurality of second semiconductor chips 200, and the plurality of second front connection pads 212 may be on the bottom surface thereof.

The second wiring layer 220 may include a plurality of second wiring patterns 222, a plurality of second wiring vias 224, and a second interconnection insulating layer 226. The plurality of second wiring vias 224 may be connected to top surfaces and/or bottom surfaces of the plurality of second wiring patterns 222. In some embodiments, the plurality of second wiring patterns 222 may be spaced apart from one another at different vertical levels, and the plurality of second wiring vias 224 may connect the plurality of second wiring patterns 222 at different vertical levels to one another. The plurality of second wiring patterns 222 and the plurality of second wiring vias 224 may be electrically connected to the plurality of second through electrodes 230. The second interconnection insulating layer 226 may be on (e.g., surround at least a portion of) the plurality of second wiring patterns 222 and the plurality of second wiring vias 224. In some embodiments, the plurality of second front connection pads 212 may be on a bottom surface of the second interconnection insulating layer 226 of the plurality of second wiring patterns 222.

The plurality of second through electrodes 230 may vertically pass through at least a part of the second substrate 202 to electrically connect the plurality of second front connection pads 212 to the plurality of second rear connection pads 214. For example, the plurality of second front connection pads 212 may be electrically connected to the plurality of second rear connection pads 214 through the plurality of second through electrodes 230, the plurality of second wiring patterns 222, and the plurality of second wiring vias 224, respectively.

Each of the plurality of first wiring patterns 122, the plurality of first wiring vias 124, the plurality of second wiring patterns 222, and the plurality of second wiring vias 224 may include a metal such as Cu, aluminum (Al), tungsten (W), titanium (Ti), tantalum (Ta), molybdenum (Mo), cobalt (Co), or nickel (Ni), an alloy of the above metals, or nitride of the above metals. The first interconnection insulating layer 126 may include a high density plasma (HDP) oxide layer, a tetraethyl orthosilicate (TEOS) oxide layer, tonen silazene (TOSZ), spin on glass (SOG), undoped silica glass (USG), or a low-k dielectric layer.

Each of the plurality of first through electrodes 130 and the plurality of second through electrodes 230 may include a conductive plug and a conductive barrier layer on or surrounding the conductive plug. The conductive plug may include Cu or W. For example, the conductive plug may include Cu, CuSn, CuMg, CuNi, CuZn, CuPd, CuAu, CuRe, CuW, W, or a W alloy. However, the inventive concept is not limited thereto. For example, the conductive plug may include one or more of Al, gold (Au), beryllium (Be), bismuth (Bi), cobalt (Co), Cu, hafnium (Hf), indium (In), manganese (Mn), molybdenum (Mo), Ni, palladium (Pb), platinum (Pt), rhodium (Rh), rhenium (Re), ruthenium (Ru), Ta, tellurium (Te), Ti, W, zinc (Zn), and zirconium (Zr), and may include one or more stacked structures. The conductive barrier layer may include at least one material selected from W, WN, WC, Ti, TiN, Ta, TaN, Ru, Co, Mn, WN, Ni, and NiB, and may include a single layer or layers.

A plurality of chip connection terminals 260 may be respectively attached onto the plurality of second front connection pads 212. Each of the plurality of chip connection terminals 260 may be between each of the plurality of first rear connection pads 114 and each of the plurality of second front connection pads 212 facing each other, or between each of the plurality of second rear connection pads 214 and each of the plurality of second front connection pads 212 facing each other. Specifically, the plurality of chip connection terminals 260 may be between the plurality of first rear connection pads 114 and the plurality of second front connection pads 212 attached to the lowermost second semiconductor chip 200 among the plurality of second semiconductor chips 200, and between the plurality of second front connection pads 212 attached to the remaining second semiconductor chips 200 among the plurality of second semiconductor chips 200 and the plurality of second rear connection pads 214 attached to the other second semiconductor chips 200 therebelow to electrically connect the first semiconductor chip 100 to the plurality of second semiconductor chips 200. In some embodiments, the plurality of chip connection terminals 260 may include conductive pillars, bumps, or solder balls.

The plurality of second front connection pads 212 to which the plurality of chip connection terminals 260 are attached may be referred to as front connection pads, the plurality of first rear connection pads 114 and the plurality of second rear connection pads 214 to which the plurality of chip connection terminals 260 are attached may be referred to as rear connection pads, and the plurality of first front connection pads 112 may be referred to as external connection pads.

In some embodiments, an uppermost second semiconductor chip 200T farthest from the first semiconductor chip 100 among the plurality of second semiconductor chips 200 may not include the plurality of second rear connection pads 214 and the plurality of second through electrodes 230. In some embodiments, a thickness of the uppermost second semiconductor chip 200T farthest from the first semiconductor chip 100 among the plurality of second semiconductor chips 200 may be greater than that of each of the remaining second semiconductor chips 200.

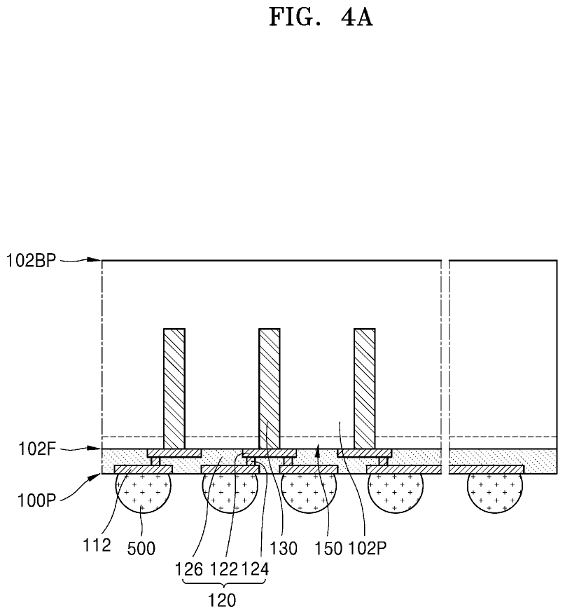

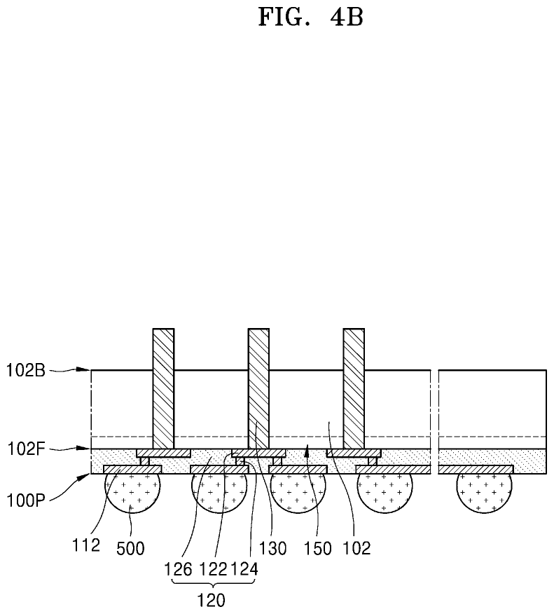

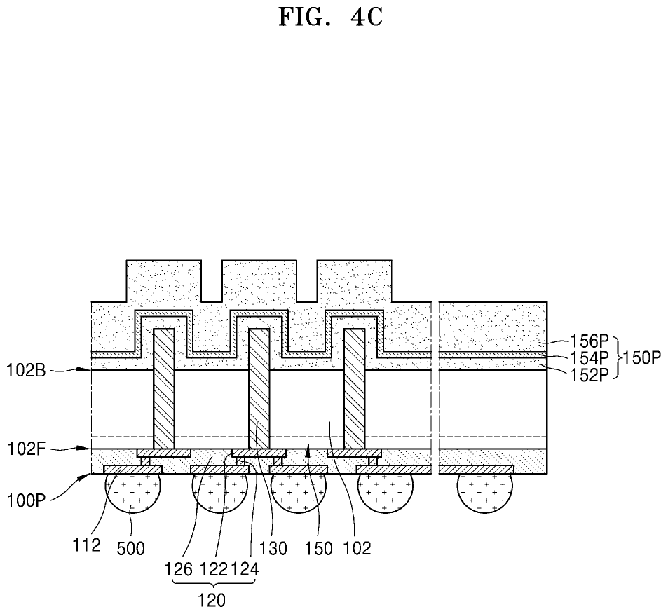

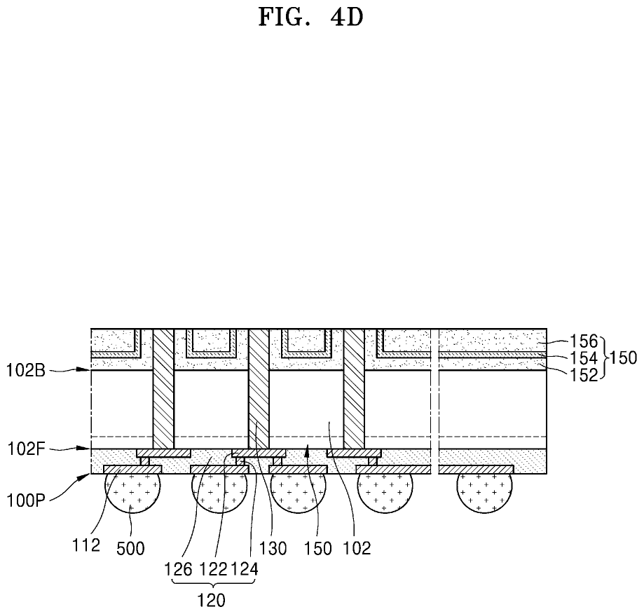

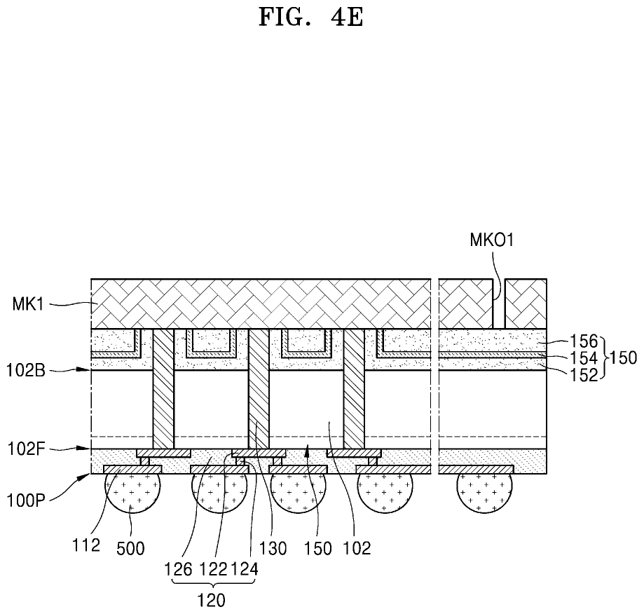

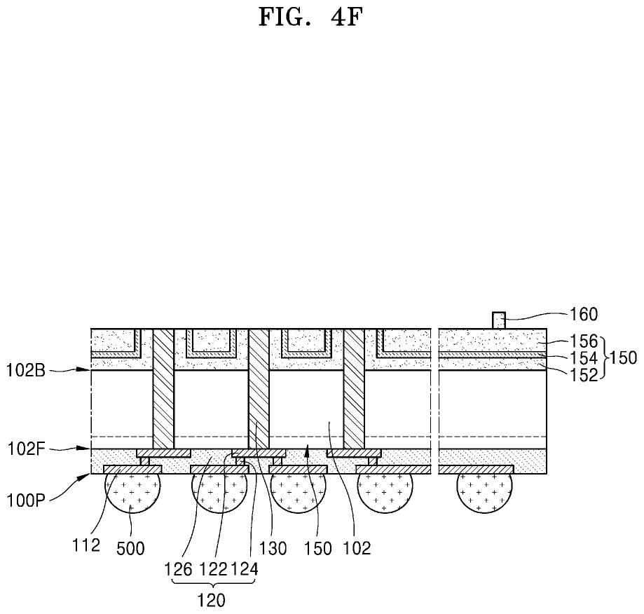

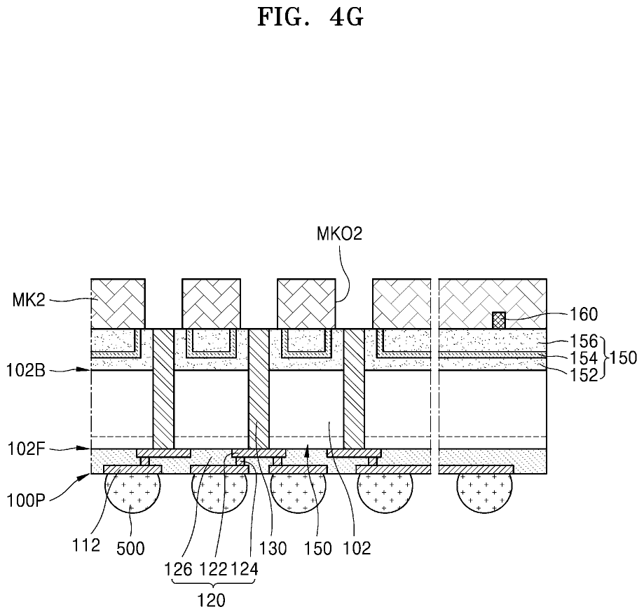

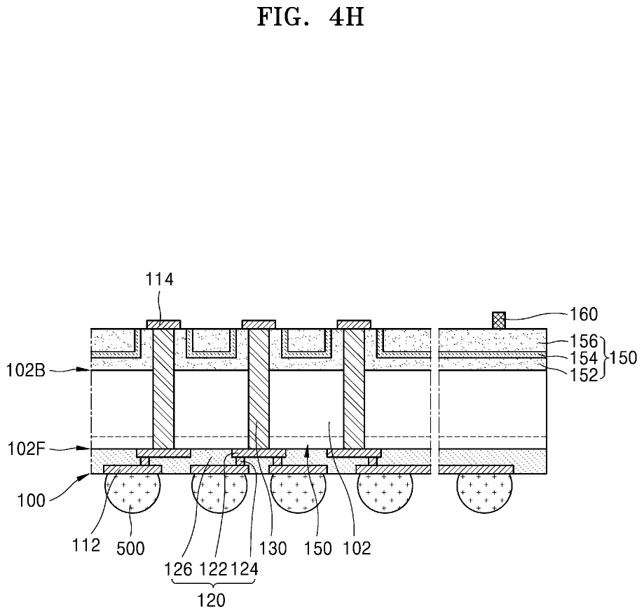

Referring to FIGS. 1A, 1B, and 4H, the first wiring layer 120 and the first protective layer 150 may cover a first active surface 102F and a first inactive surface 102B of the first substrate 102.

The first protective layer 150 may have a stacked structure of a first lower protective layer 152, a first intermediate protective layer 154, and a first upper protective layer 156 sequentially stacked on the first inactive surface 102B of the first substrate 102. The first intermediate protective layer 154 may include a material different from that of the first lower protective layer 152, and the first upper protective layer 156 may include a material different from that of the first intermediate protective layer 154. In some embodiments, the first lower protective layer 152 may include oxide, the first intermediate protective layer 154 may include nitride, and the first upper protective layer 156 may include oxide. For example, the first lower protective layer 152 may include silicon oxide, the first intermediate protective layer 154 may include silicon nitride, and the first upper protective layer 156 may include silicon oxide.

The plurality of first through electrodes 130 may protrude onto the first inactive surface 102B of the first substrate 102. Parts of the plurality of first through electrodes 130 may be buried in the first substrate 102, and the other parts of the plurality of first through electrodes 130 may protrude from the first inactive surface 102B to the outside of the first substrate 102. The first protective layer 150 may be on sidewalls of (e.g., surround) the other parts of the plurality of first through electrodes 130 on the first inactive surface 102B.

The first lower protective layer 152 may cover the first inactive surface 102B of the first substrate 102 and parts of side surfaces of the plurality of first through electrodes 130. In some embodiments, the first lower protective layer 152 may cover other parts of the side surfaces of the plurality of first through electrodes 130 protruding or extending onto the first inactive surface 102B of the first substrate 102. The first lower protective layer 152 may cover the first inactive surface 102B and other parts of the side surfaces of the plurality of first through electrodes 130 with substantially the same thickness. For example, the first lower protective layer 152 may have a thickness of about 0.5 μm to about 1 μm.

The first intermediate protective layer 154 may cover the first lower protective layer 152. The first intermediate protective layer 154 may cover the first lower protective layer 152 covering the first inactive surface 102B and other parts of the side surfaces of the plurality of first through electrodes 130 with substantially the same thickness. For example, the first intermediate protective layer 154 may have a thickness of about 0.5 μm to about 1 μm. In some embodiments, the first intermediate protective layer 154 may have substantially the same thickness as the first lower protective layer 152 or may be thinner than the first lower protective layer 152.

The first upper protective layer 156 may cover the first intermediate protective layer 154. For example, the first upper protective layer 156 may have a thickness of about 1 μm to about 3 μm. The first upper protective layer 156 may be formed such that a top surface of the first upper protective layer 156 is at the same vertical level as the top end of the first lower protective layer 152 and the top end of the first intermediate protective layer 154. For example, the first lower protective layer 152 may conformally cover the first inactive surface 102B and other parts of the side surfaces of the plurality of first through electrodes 130, the first upper protective layer 156 may conformally cover the first intermediate protective layer 154, and the first upper protective layer 156 may fill a space limited by the first intermediate protective layer 154, that is, a space limited by a part of the first lower protective layer 152 covering the first inactive surface 102B and a part of the first intermediate protective layer 154, and another part of the first lower protective layer 152 covering side surfaces of other parts of the plurality of first through electrodes 130 and another part of the first intermediate protective layer 154.

In some embodiments, the top end of the first lower protective layer 152, the top end of the first intermediate protective layer 154, the top surface of the first upper protective layer 156, and top surfaces of the plurality of first through electrodes 130 may be coplanar at the same vertical level.

The second protective layer 250 may have a stacked structure of a second lower protective layer 252, a second intermediate protective layer 254, and a second upper protective layer 256 sequentially stacked on the second inactive surface of the second substrate 202. In some embodiments, the second lower protective layer 252 may include oxide, the second intermediate protective layer 254 may include nitride, and the second upper protective layer 256 may include oxide.

The plurality of second through electrodes 230, the second lower protective layer 252, the second intermediate protective layer 254, and the second upper protective layer 256 may be formed substantially the same as the first lower protective layer 152, the first intermediate protective layer 154, and the first upper protective layer 156 to have substantially the same shape as the first lower protective layer 152, the first intermediate protective layer 154, and the first upper protective layer 156.

For example, similar to the plurality of first through electrodes 130, the plurality of second through electrodes 230 may protrude onto the second inactive surface of the second substrate 202, and similar to the first protective layer 150, the second protective layer 250 may be on (e.g., surround) the plurality of second through electrodes 230 protruding or extending onto the second inactive surface of the second substrate 202.

For example, similar to the first lower protective layer 152, the first intermediate protective layer 154, and the first upper protective layer 156, the second lower protective layer 252 may cover the second inactive surface of the second substrate 202 and parts of side surfaces of the plurality of second through electrodes 230 with substantially the same thickness, the second intermediate protective layer 254 may be on (e.g. to cover) the second lower protective layer 252 on or surrounding the second inactive surface of the second substrate 202 and parts of the side surfaces of the plurality of second through electrodes 230 with substantially the same thickness, and the second upper protective layer 256 may cover the second intermediate protective layer 254. In some embodiments, the top end of the second lower protective layer 252, the top end of the second intermediate protective layer 254, a top surface of the second upper protective layer 256, and top surfaces of the plurality of second through electrodes 230 may be at the same vertical level to be coplanar.

The first semiconductor chip 100 includes a support structure 160 on the first protective layer 150. The support structure 160 may be on a portion of the first protective layer 150, which does not overlap the plurality of second semiconductor chips 200 in the vertical direction. The support structure 160 may protrude from the top surface of the first semiconductor chip 100, that is, the top surface of the first protective layer 150. The support structure 160 may be positioned on the first upper protective layer 156. In some embodiments, the support structure 160 and the first upper protective layer 156 may include the same material. For example, the support structure 160 may include silicon oxide.

The support structure 160 may have a first height H1 and a first width W1. The first width W1 may mean a width of the support structure 160 in a direction from the edge of the lowermost second semiconductor chip 200 to the edge of the first semiconductor chip 100 in a plan view. The support structure 160 with the first width W1 may be horizontally spaced apart from the edge of the first semiconductor chip 100 and the edge of the lowermost second semiconductor chip 200, and may extend along the edge of the first semiconductor chip 100 and the edge of the lowermost second semiconductor chip 200. In some embodiments, the first height H1 may be about 3 μm to about 15 μm, and the first width W1 may be about 3 μm to about 15 μm.

The support structure 160 may be covered with the first insulating adhesive layer 270a. For example, the first insulating adhesive layer 270a may cover a top surface and side surfaces of the support structure 160. The support structure 160 may be enclosed (e.g., completely surrounded) by the first upper protective layer 156 and the first insulating adhesive layer 270a. For example, the first upper protective layer 156 may be on or cover a bottom surface of the support structure 160, and the first insulating adhesive layer 270a may be on or cover the top and side surfaces of the support structure 160.

In a plan view, the support structure 160 may be between the edge of the lowermost second semiconductor chip 200 and the edge of the first insulating adhesive layer 270a. In a plan view, the support structure 160 may be horizontally spaced apart from the edge of the lowermost second semiconductor chip 200 by a first distance D1, and may be apart from an edge of the first insulating adhesive layer 270a by a second distance D2. In a plan view, the edge of the first insulating adhesive layer 270a may be horizontally spaced apart from the edge of the first semiconductor chip 100 and the edge of the lowermost second semiconductor chip 200. In some embodiments, the first distance D1 may be greater than the second distance D2. For example, the first distance D1 may be about 100 μm to about 200 μm, and the second distance D2 may be about 30 μm to about 130 μm.

In a process of forming the semiconductor package 1, the first insulating adhesive layer 270a may be exposed to a relatively high thermal compression environment. For example, the first insulating adhesive layer 270a may be repeatedly exposed to a thermal compression environment not only by a process of attaching the first insulating adhesive layer 270a to a bottom surface of the lowermost second semiconductor chip 200 of the plurality of second semiconductor chips 200 and performing a thermal compression bonding process to attach the lowermost second semiconductor chip 200 to the first semiconductor chip 100 but also by a thermal compression bonding process of attaching the second insulating adhesive layer 270b, the third insulating adhesive layer 270c, and the fourth insulating adhesive layer 270d to the remaining second semiconductor chips 200, respectively, and attaching the remaining second semiconductor chips 200 to the lowermost second semiconductor chip 200. In this case, warpage may occur in the first insulating adhesive layer 270a, and a crack, in which the first insulating adhesive layer 270a is separated from the first semiconductor chip 100, may progress from the edge of the first insulating adhesive layer 270a toward the inside of the first insulating adhesive layer 270a so that the first semiconductor chip 100 may separate from the plurality of second semiconductor chips 200.

However, the semiconductor package 1 according to the inventive concept has the support structure 160 horizontally spaced apart from the edge of the first insulating adhesive layer 270a (e.g., in a plan view) by the second distance D2. Due to the support structure 160, the crack in which the first insulating adhesive layer 270a is separated from the first semiconductor chip 100 may not progress inward from the support structure 160 of the semiconductor package 1, so that the first semiconductor chip 100 may not separate from the plurality of second semiconductor chips 200. Therefore, the structural reliability of the semiconductor package 1 may be secured and the electrical connection reliability between the first semiconductor chip 100 and the plurality of second semiconductor chips 200 may be secured.

Each of the plurality of insulating adhesive layers 270 may include a non-conductive film (NCF), a non-conductive paste (NCP), an insulating polymer, or an epoxy resin. The plurality of insulating adhesive layers 270 may be on sidewalls of (e.g., to surround) the plurality of chip connection terminals 260 and may fill gaps between the first semiconductor chip 100 and the plurality of second semiconductor chips 200.

The first semiconductor chip 100 and the plurality of second semiconductor chips 200 may be spaced apart from one another in the vertical direction with the plurality of insulating adhesive layers 270 therebetween. The first semiconductor chip 100 and the plurality of second semiconductor chips 200 may be spaced apart from one another by a vertical distance G1. The vertical distance G1 may be equal to a thickness of each of the plurality of insulating adhesive layers 270 between the first semiconductor chip 100 and the plurality of second semiconductor chips 200. For example, the vertical distance G1 may be about 6 μm to about 20 μm. In some embodiments, the vertical distance G1 between the first semiconductor chip 100 and the lowermost second semiconductor chip 200 of the plurality of second semiconductor chips 200 may be greater than the first height H1 of the support structure 160. The vertical distance G1 may be a thickness of a portion of the first insulating adhesive layer 270a, which fills the gap between the first semiconductor chip 100 and the lowermost second semiconductor chip 200 of the plurality of second semiconductor chips 200. For example, the top surface of the support structure 160 may be at a vertical level higher than the top surface of the first semiconductor chip 100 and lower than a bottom surface of the lowermost second semiconductor chip 200 of the plurality of second semiconductor chips 200.

The plurality of insulating adhesive layers 270 may protrude from bottoms of the plurality of second semiconductor chips 200 to further extend outward in a horizontal direction from the edges of the plurality of second semiconductor chips 200. In the horizontal direction from the edges of the plurality of second semiconductor chips 200, the first insulating adhesive layer 270a may protrude to further extend outward to have a first protrusion length P1, the second insulating adhesive layer 270b may protrude to further extend outward to have a second protrusion length P2, and the third insulating adhesive layer 270c may protrude to further extend outward to have a third protrusion length P3. In some embodiments, the first protrusion length P1 may be greater than each of the second protrusion length P2 and the third protrusion length P3. That is, the lowermost insulating adhesive layer of the plurality of insulating adhesive layers 270, that is, the first insulating adhesive layer 270a between the first semiconductor chip 100 and the lowermost second semiconductor chip 200 of the plurality of second semiconductor chips 200, may protrude to further extend outward in the horizontal direction from the edges of the plurality of second semiconductor chips 200 than the second insulating adhesive layer 270b, the third insulating adhesive layer 270c, and the fourth insulating adhesive layer 270d. It is illustrated in FIG. 1A that the second protrusion length P2 of the second insulating adhesive layer 270b is greater than the third protrusion length P3 of the third insulating adhesive layer 270c. However, the inventive concept is not limited thereto. For example, the protrusion length of the fourth insulating adhesive layer 270d may be greater than each of the second protrusion length P2 of the second insulating adhesive layer 270b and the third protrusion length P3 of the third insulating adhesive layer 270c. Alternatively, for example, the third protrusion length P3 of the third insulating adhesive layer 270c may be greater than the second protrusion length P2 of the second insulating adhesive layer 270b. Alternatively, for example, the third protrusion length P3 of the third insulating adhesive layer 270c may be greater than the protrusion length of the fourth insulating adhesive layer 270d. The semiconductor package 1 may further include a molding layer 400 on or surrounding the plurality of second semiconductor chips 200 and the plurality of insulating adhesive layers 270 on the first semiconductor chip 100. The molding layer 400 may include, for example, an epoxy mold compound (EMC). In some embodiments, the molding layer 400 may cover side surfaces of the plurality of second semiconductor chips 200, side surfaces of the plurality of insulating adhesive layers 270, and a top surface of the uppermost second semiconductor chip 200T of the plurality of second semiconductor chips 200. In other embodiments, the molding layer 400 may cover the side surfaces of the plurality of second semiconductor chips 200 and the side surfaces of the plurality of insulating adhesive layers 270 and may not cover the top surface of the uppermost second semiconductor chip 200T of the plurality of second semiconductor chips 200. For example, a top surface of the molding layer 400 and the top surface of the uppermost second semiconductor chip 200T may be coplanar with one another.

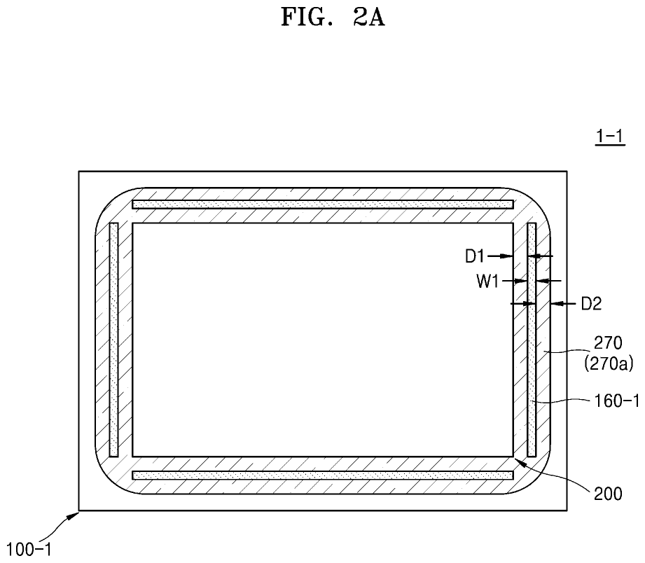

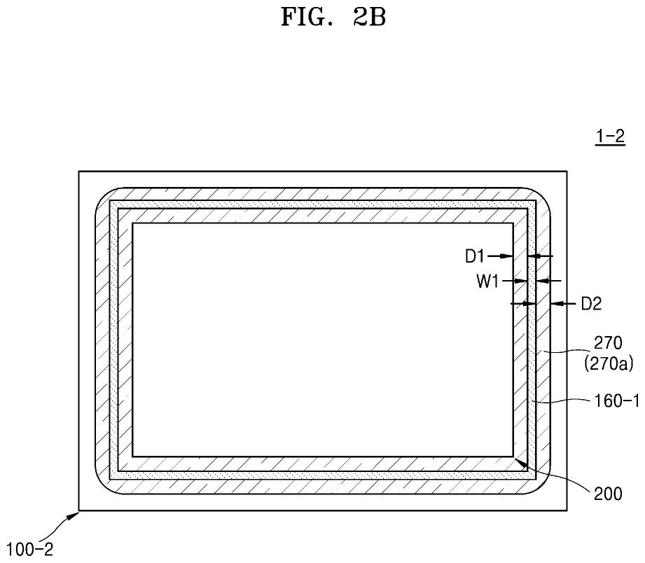

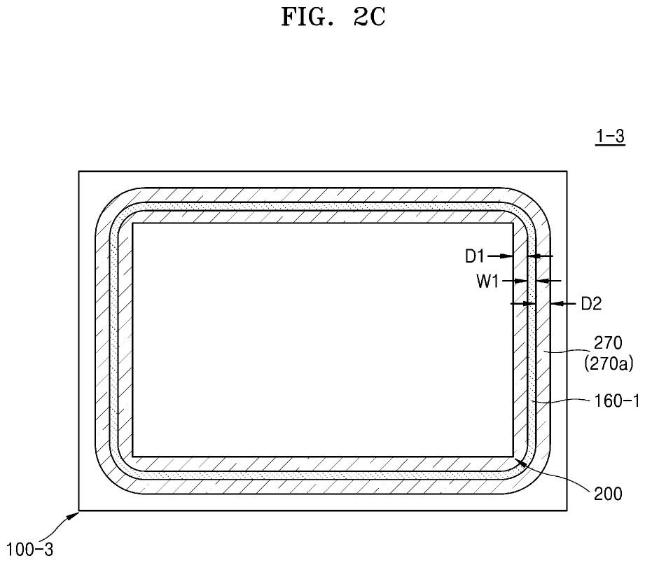

FIGS. 2A to 2C are planar views illustrating planar configurations of some components of semiconductor packages 1-1, 1-2, and 1-3 according to embodiments. Specifically, FIGS. 2A to 2C are planar views illustrating a planar configuration of some components of the semiconductor package 1 illustrated in FIGS. 1A and 1B, and in FIGS. 2A to 2C, the same reference numerals as in FIGS. 1A and 1B denote substantially the same members, and description previously given with reference to FIGS. 1A and 1B may be omitted.

Referring to FIG. 2A, the semiconductor package 1-1 may include a first semiconductor chip 100-1, a plurality of second semiconductor chips 200 stacked on the first semiconductor chip 100-1, and a plurality of insulating adhesive layers 270 between the first semiconductor chip 100-1 and the plurality of second semiconductor chips 200. The semiconductor package 1-1 including the first semiconductor chip 100-1 may be the semiconductor package 1 including the first semiconductor chip 100 illustrated in FIG. 1A. The plurality of insulating adhesive layers 270 may include a first insulating adhesive layer 270a between the first semiconductor chip 100-1 and the lowermost second semiconductor chip 200 of the plurality of second semiconductor chips 200.

A horizontal width of the first semiconductor chip 100-1 may be greater than that of each of the plurality of second semiconductor chips 200. An edge of each of the plurality of second semiconductor chips 200 may not be aligned in the vertical direction with an edge of the first semiconductor chip 100-1. For example, the plurality of second semiconductor chips 200 may all overlap the first semiconductor chip 100-1 in the vertical direction.

A support structure 160-1 with a first width W1 may be horizontally spaced apart from the edge of the first semiconductor chip 100-1 and the edge of the lowermost second semiconductor chip 200, and may extend along the edge of the first semiconductor chip 100-1 and the edge of the lowermost second semiconductor chip 200. The first insulating adhesive layer 270a may cover the support structure 160-1. The support structure 160-1 may be the support structure 160 illustrated in FIGS. 1A and 1B.

In a plan view, the support structure 160-1 may be horizontally spaced apart from the edge of the lowermost second semiconductor chip 200 by a first distance D1, and may be horizontally spaced apart from an edge of the first insulating adhesive layer 270a by a second distance D2. In some embodiments, the first distance D1 may be greater than the second distance D2.

In some embodiments, a plurality of support structures 160-1 may correspond to edges of the first semiconductor chip 100-1 and the plurality of second semiconductor chips 200 and may be spaced apart from one another. For example, when the first semiconductor chip 100-1 and the plurality of second semiconductor chips 200 have four edges, the semiconductor package 1-1 may include four support structures 160-1 corresponding to the four edges of the first semiconductor chip 100-1 and the plurality of second semiconductor chips 200 and spaced apart from one another. For example, each of the four support structures 160-1 may be line-shaped or bar-shaped. Extension lengths of the four support structures 160-1 may be equal to or greater than lengths of the four edges of the first semiconductor chip 100-1 and the plurality of second semiconductor chips 200.

Referring to FIG. 2B, the semiconductor package 1-2 may include a first semiconductor chip 100-2, a plurality of second semiconductor chips 200 stacked on the first semiconductor chip 100-2, and a plurality of insulating adhesive layers 270 between the first semiconductor chip 100-2 and the plurality of second semiconductor chips 200. The semiconductor package 1-2 including the first semiconductor chip 100-2 may be the semiconductor package 1 including the first semiconductor chip 100 illustrated in FIG. 1A. The plurality of insulating adhesive layers 270 may include a first insulating adhesive layer 270a between the first semiconductor chip 100-2 and the lowermost second semiconductor chip 200 of the plurality of second semiconductor chips 200.

A horizontal width of the first semiconductor chip 100-2 may be greater than that of each of the plurality of second semiconductor chips 200. An edge of each of the plurality of second semiconductor chips 200 may not be aligned in the vertical direction with an edge of the first semiconductor chip 100-2. For example, the plurality of second semiconductor chips 200 may all overlap the first semiconductor chip 100-2 in the vertical direction.

A support structure 160-2 with a first width W1 may be horizontally spaced apart from the edge of the first semiconductor chip 100-2 and the edge of the lowermost second semiconductor chip 200, and may extend along the edge of the first semiconductor chip 100-2 and the edge of the lowermost second semiconductor chip 200. The first insulating adhesive layer 270a may cover the support structure 160-2. The support structure 160-2 may be the support structure 160 illustrated in FIGS. 1A and 1B.

In a plan view, the support structure 160-2 may be horizontally spaced apart from the edge of the lowermost second semiconductor chip 200 by a first distance D1, and may be horizontally spaced apart from an edge of the first insulating adhesive layer 270a by a second distance D2. In some embodiments, the first distance D1 may be greater than the second distance D2.

In some embodiments, in a plan view, the support structure 160-2 may extend around a perimeter of or completely surround the first semiconductor chip 100-2 and the plurality of second semiconductor chips 200. For example, the support structure 160-2 has a first width W1 in a plan view and may extend in a rectangular shape.

Referring to FIG. 2C, the semiconductor package 1-3 may include a first semiconductor chip 100-3, a plurality of second semiconductor chips 200 stacked on the first semiconductor chip 100-3, and a plurality of insulating adhesive layers 270 between the first semiconductor chip 100-3 and the plurality of second semiconductor chips 200. The semiconductor package 1-3 including the first semiconductor chip 100-3 may be the semiconductor package 1 including the first semiconductor chip 100 illustrated in FIG. 1A. The plurality of insulating adhesive layers 270 may include a first insulating adhesive layer 270a between the first semiconductor chip 100-3 and the lowermost second semiconductor chip 200 of the plurality of second semiconductor chips 200.

A horizontal width of the first semiconductor chip 100-3 may be greater than that of each of the plurality of second semiconductor chips 200. An edge of each of the plurality of second semiconductor chips 200 may not be aligned in the vertical direction with an edge of the first semiconductor chip 100-3. For example, the plurality of second semiconductor chips 200 may all overlap the first semiconductor chip 100-3 in the vertical direction.

A support structure 160-3 with a first width W1 may be horizontally spaced apart from the edge of the first semiconductor chip 100-3 and the edge of the lowermost second semiconductor chip 200, and may extend along the edge of the first semiconductor chip 100-3 and the edge of the lowermost second semiconductor chip 200. The first insulating adhesive layer 270a may cover the support structure 160-3. The support structure 160-3 may be the support structure 160 illustrated in FIGS. 1A and 1B.

In a plan view, the support structure 160-3 may be horizontally spaced apart from the edge of the lowermost second semiconductor chip 200 by a first distance D1, and may be horizontally spaced apart from an edge of the first insulating adhesive layer 270a by a second distance D2. In some embodiments, the first distance D1 may be greater than the second distance D2.

In some embodiments, in a plan view, the support structure 160-3 may extend around a perimeter of or completely surround the first semiconductor chip 100-2 and the plurality of second semiconductor chips 200. For example, the support structure 160-2 has a first width W1 in a plan view and may extend in a rectangular shape with rounded corners.

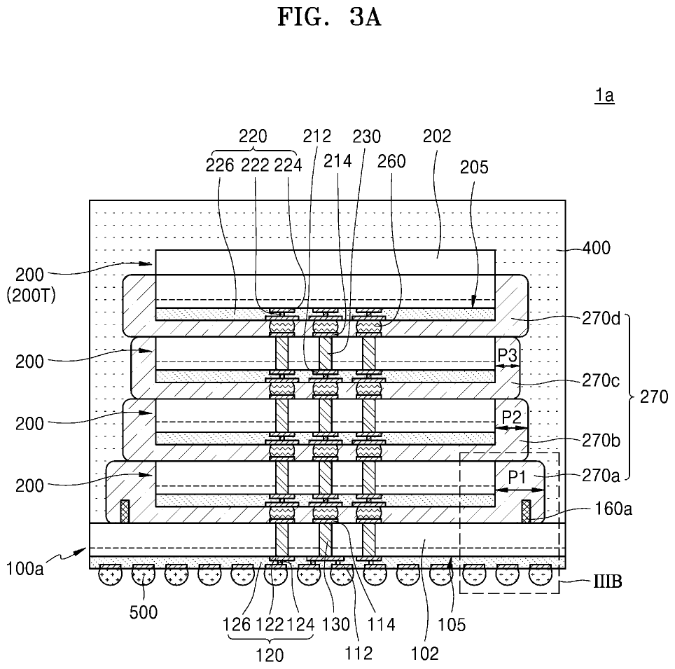

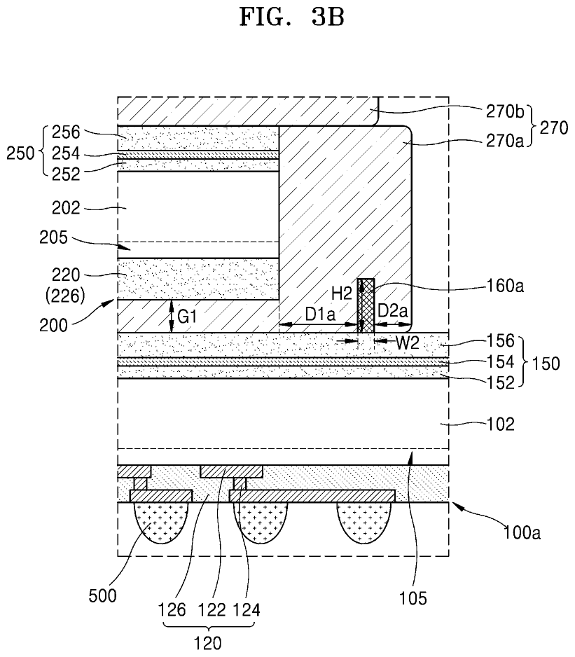

FIGS. 3A and 3B are a cross-sectional view and an enlarged cross-sectional view of a semiconductor package 1a according to an embodiment. In FIGS. 3A and 3B, the same reference numerals as in FIGS. 1A and 1B denote substantially the same members, and description previously given with reference to FIGS. 1A and 1B may be omitted.

Referring to FIGS. 3A and 3B, the semiconductor package 1a may include a first semiconductor chip 100a, a plurality of second semiconductor chips 200 stacked on the first semiconductor chip 100a, and a plurality of insulating adhesive layers 270 between the first semiconductor chip 100a and the plurality of second semiconductor chips 200.

A horizontal width of the first semiconductor chip 100a may be greater than that of each of the plurality of second semiconductor chips 200. An edge of each of the plurality of second semiconductor chips 200 may not be aligned in the vertical direction with an edge of the first semiconductor chip 100a. For example, the plurality of second semiconductor chips 200 may all overlap the first semiconductor chip 100a in the vertical direction.

The plurality of insulating adhesive layers 270 may include a first insulating adhesive layer 270a, a second insulating adhesive layer 270b, a third insulating adhesive layer 270c, and a fourth insulating adhesive layer 270d. The first insulating adhesive layer 270a may be between the first semiconductor chip 100a and the lowermost second semiconductor chip 200 of the plurality of second semiconductor chips 200. Each of the second insulating adhesive layer 270b, the third insulating adhesive layer 270c, and the fourth insulating adhesive layer 270d may be between each two adjacent second semiconductor chips 200 among the four second semiconductor chips 200. The first insulating adhesive layer 270a, the second insulating adhesive layer 270b, the third insulating adhesive layer 270c, and the fourth insulating adhesive layer 270d may be sequentially arranged away from the first semiconductor chip 100a. That is, the first insulating adhesive layer 270a, the second insulating adhesive layer 270b, the third insulating adhesive layer 270c, and the fourth insulating adhesive layer 270d are successively further away from the first semiconductor chip 100a with the first insulating adhesive layer 270 a being the closest to the first semiconductor chip 100a and the fourth insulating adhesive layer 270d being the furthest from the first semiconductor chip 100a.

The first semiconductor chip 100a includes a first substrate 102, a first wiring layer 120, a plurality of first through electrodes 130, and a first protective layer 150. A plurality of first front connection pads 112 may be attached to a bottom surface of the first semiconductor chip 100a, and a plurality of first rear connection pads 114 may be attached to a top surface thereof. Each of the plurality of second semiconductor chips 200 includes a second substrate 202, a second wiring layer 220, a plurality of second through electrodes 230, and a second protective layer 250. A plurality of second front connection pads 212 may be attached to a bottom surface of each of the plurality of second semiconductor chips 200, and a plurality of second rear connection pads 214 may be attached to a top surface thereof.

The first semiconductor chip 100a and each of the plurality of second semiconductor chips 200 may include a first semiconductor device 105 and a second semiconductor device 205 each configured by the plurality of individual devices. The first semiconductor device 105 may be on the first active surface of the first substrate 102, and the second semiconductor device 205 may be on the second active surface of the second substrate 202.

The first semiconductor chip 100a and the plurality of second semiconductor chips 200 included in the semiconductor package 1a may be sequentially stacked in a face down form in which the first active surface and the plurality of second active surfaces face downward. For example, the first active surface of the first substrate 102 included in the first semiconductor chip 100a may face a side opposite to the plurality of second semiconductor chips 200, and the first inactive surface may face the plurality of second semiconductor chips 200. The second active surface of the second substrate 202 included in each of the plurality of second semiconductor chips 200 may face the first semiconductor chip 100a, and the second inactive surface thereof may face a side opposite to the first semiconductor chip 100a.

Each of the first semiconductor chip 100a and the plurality of second semiconductor chips 200 may include DRAM, SRAM, flash memory, EEPROM, PRAM, MRAM, or RRAM.

In some embodiments, the first semiconductor chip 100a may not include a memory cell. The second semiconductor device included in each of the plurality of second semiconductor chips 200 may include a memory cell. For example, the first semiconductor chip 100a may be a buffer chip for controlling the plurality of second semiconductor chips 200.

In some embodiments, the first semiconductor chip 100a may be a buffer chip for controlling HBM DRAM, and the plurality of second semiconductor chips 200 may be memory cell chips having cells of the HBM DRAM controlled by the first semiconductor chip 100a. The first semiconductor chip 100a may be referred to as a buffer chip or a master chip, and the plurality of second semiconductor chips 200 may be referred to as memory cell chips or slave chips. The first semiconductor chip 100a and the plurality of second semiconductor chips 200 stacked on the first semiconductor chip 100a may be referred to as an HBM DRAM device or an HBM DRAM chip.

The plurality of chip connection terminals 260 may be between the plurality of first rear connection pads 114 and the plurality of second front connection pads 212 attached to the lowermost second semiconductor chip 200 of the plurality of second semiconductor chips 200, and between the plurality of second front connection pads 212 attached to the remaining second semiconductor chips 200 among the plurality of second semiconductor chips 200 and the plurality of second rear connection pads 214 attached to the other second semiconductor chips 200 therebelow to electrically connect the first semiconductor chip 100a to the plurality of second semiconductor chips 200.

Referring to FIGS. 3A, 3B, and 4H, the first wiring layer 120 and the first protective layer 150 may cover a first active surface 102F and a first inactive surface 102B of the first substrate 102.

The first protective layer 150 may have a stacked structure of a first lower protective layer 152, a first intermediate protective layer 154, and a first upper protective layer 156 sequentially stacked on the first inactive surface 102B of the first substrate 102. The first protective layer 150 may be on sidewalls of (e.g., to surround) parts of the plurality of first through electrodes 130 on the first inactive surface 102B.

The second protective layer 250 may have a stacked structure of a second lower protective layer 252, a second intermediate protective layer 254, and a second upper protective layer 256 sequentially stacked on the second inactive surface of the second substrate 202. The second protective layer 250 may be on or surround at least parts of the plurality of second through electrodes 230 extending onto the second inactive surface of the second substrate 202.

The first semiconductor chip 100a includes a support structure 160a on the first protective layer 150. The support structure 160a may be positioned on the first upper protective layer 156. In some embodiments, the support structure 160a and the first upper protective layer 156 may include the same material. For example, the support structure 160a may include silicon oxide.

The support structure 160a may have a second height H2 and a second width W2. The second width W2 may mean a width of the support structure 160a in a direction from the edge of the lowermost second semiconductor chip 200 to the edge of the first semiconductor chip 100a in a plan view. The support structure 160a with the second width W2 may be horizontally spaced apart from the edge of the first semiconductor chip 100a and the edge of the lowermost second semiconductor chip 200, and may extend along the edge of the first semiconductor chip 100a and the edge of the lowermost second semiconductor chip 200. In some embodiments, the second height H2 may be about 8 μm to about 25 μm, and the second width W2 may be about 8 μm to about 25 μm.

The support structure 160a may be covered with the first insulating adhesive layer 270a. For example, the first insulating adhesive layer 270a may cover a top surface and side surfaces of the support structure 160a. The support structure 160a may be enclosed or surrounded by the first upper protective layer 156 and the first insulating adhesive layer 270a. For example, the first upper protective layer 156 may be on or cover a bottom surface of the support structure 160a, and the first insulating adhesive layer 270a may be on or cover the top and side surfaces of the support structure 160a.

In a plan view, the support structure 160a may be horizontally spaced apart from the edge of the lowermost second semiconductor chip 200 by a first distance D1a, and may be horizontally spaced apart from an edge of the first insulating adhesive layer 270a by a second distance D2a. In some embodiments, the first distance D1a may be greater than the second distance D2a. For example, the first distance D1a may be about 100 μm to about 200 μm, and the second distance D2a may be about 30 μm to about 130 μm.

The first semiconductor chip 100a and the plurality of second semiconductor chips 200 may be spaced apart from one another in the vertical direction with the plurality of insulating adhesive layers 270 therebetween. The first semiconductor chip 100a and the plurality of second semiconductor chips 200 may be spaced apart from one another by a vertical distance G1. The vertical distance G1 may be equal to a thickness of each of the plurality of insulating adhesive layers 270 between the first semiconductor chip 100a and the plurality of second semiconductor chips 200. In some embodiments, the vertical distance G1 between the first semiconductor chip 100a and the lowermost second semiconductor chip 200 of the plurality of second semiconductor chips 200 may be less than the second height H2 of the support structure 160a. For example, the top surface of the support structure 160a may be at a vertical level higher than a bottom surface of the lowermost second semiconductor chip 200 of the plurality of second semiconductor chips 200 and lower than a top surface of the lowermost second semiconductor chip 200 of the plurality of second semiconductor chips 200.

The semiconductor package 1a may further include a molding layer 400 on or surrounding the plurality of second semiconductor chips 200 and the plurality of insulating adhesive layers 270 on the first semiconductor chip 100a.

FIGS. 4A to 4H are cross-sectional views illustrating a method of manufacturing a first semiconductor chip included in a semiconductor package according to an embodiment.

Specifically, FIGS. 4A to 4H are cross-sectional views illustrating a method of manufacturing the first semiconductor chip 100 included in the semiconductor package 1 illustrated in FIGS. 1A and 1B, and in FIGS. 4A to 4H, the same reference numerals as in FIGS. 1A and 1B denote substantially the same members, and description previously given with reference to FIGS. 1A and 1B may be omitted.

Referring to FIG. 4A, a preliminary semiconductor chip 100P is prepared. The preliminary semiconductor chip 100P includes a preliminary substrate 102P, a first wiring layer 120, and a plurality of first through electrodes 130. A plurality of first front connection pads 112 may be attached to a bottom surface of the preliminary semiconductor chip 100P.

The preliminary substrate 102P may have a first active surface 102F and a preliminary inactive surface 102BP opposite to the first active surface 102F. The preliminary semiconductor chip 100P may include a first semiconductor device 105. The first semiconductor device 105 may be on the first active surface 102F of the preliminary substrate 102P. The first wiring layer 120 may be on the first active surface 102F of the preliminary substrate 102P, and the plurality of first front connection pads 112 may be on a bottom surface of the first wiring layer 120. The first wiring layer 120 may include a plurality of first wiring patterns 122, a plurality of first wiring vias 124, and a first interconnection insulating layer 126.

The plurality of first through electrodes 130 may vertically pass through at least a part of the preliminary substrate 102P to be electrically connected to the plurality of first front connection pads 112. For example, the plurality of first front connection pads 112 may be electrically connected to the plurality of first through electrodes 130 through the plurality of first wiring patterns 122 and the plurality of first wiring vias 124. The plurality of first through electrodes 130 may extend in the preliminary substrate 102P in the vertical direction, and may not extend to the preliminary inactive surface 102BP. That is, upper portions including top surfaces of the plurality of first through electrodes 130 may be buried in the preliminary substrate 102P and may not be exposed to the outside.

Referring to FIGS. 4A and 4B, a part of the preliminary substrate 102P is removed from the preliminary inactive surface 102BP to form a first substrate 102 having the first active surface 102F and the first inactive surface 102B opposite to the first active surface 102F.

As a result of forming the first substrate 102 by removing a part of the preliminary substrate 102P, upper parts of the plurality of first through electrodes 130 may protrude onto the first inactive surface 102B of the first substrate 102. Parts of the plurality of first through electrodes 130 may be buried in the first substrate 102, and the other parts of the plurality of first through electrodes 130 may protrude from the first inactive surface 102B to the outside of the first substrate 102.

Referring to FIG. 4C, a preliminary lower protective layer 152P, a preliminary intermediate protective layer 154P, and a preliminary upper protective layer 156P are sequentially formed on the first inactive surface 102B of the first substrate 102 to form a preliminary protective layer 150P having a stacked structure of the preliminary lower protective layer 152P, the preliminary intermediate protective layer 154P, and the preliminary upper protective layer 156P. The preliminary lower protective layer 152P, the preliminary intermediate protective layer 154P, and the preliminary upper protective layer 156P may sequentially conformally cover the first inactive surface 102B of the first substrate 102 and the upper parts of the plurality of first through electrodes 130. For example, the preliminary lower protective layer 152P may conformally cover the first inactive surface 102B of the first substrate 102 and the top surfaces of the plurality of first through electrodes 130 and side surfaces of the upper parts of the plurality of first through electrodes 130 extending onto the first inactive surface 102B of the first substrate 102, the preliminary intermediate protective layer 154P may conformally cover a top surface of the preliminary lower protective layer 152P, and the preliminary upper protective layer 156P may conformally cover a top surface of the preliminary intermediate protective layer 154P. In some embodiments, the preliminary upper protective layer 156P may have a sufficient thickness to cover all of the preliminary intermediate protective layer 154P. For example, a portion of a top surface of the preliminary upper protective layer 156P at the lowest vertical level may be at a vertical level higher than a portion of the top surface of the preliminary intermediate protective layer 154P at the highest vertical level. Alternatively, for example, a portion of the top surface of the preliminary upper protective layer 156P at the lowest vertical level may be at a vertical level higher than the top surfaces of the plurality of first through electrodes 130.

For example, the preliminary lower protective layer 152P may have a thickness of about 0.5 μm to about 1 μm, the preliminary intermediate protective layer 154P may have a thickness of about 0.5 μm to about 1 μm, and the preliminary upper protective layer 156P may have a thickness of about 2 μm to about 6 μm.

Referring to FIGS. 4C and 4D, a part of the preliminary protective layer 150P having the stacked structure of the preliminary lower protective layer 152P, the preliminary intermediate protective layer 154P, and the preliminary upper protective layer 156P is removed to form a first protective layer 150 having a stacked structure of a first lower protective layer 152, a first intermediate protective layer 154, and a first upper protective layer 156.

The first protective layer 150 may be formed by removing an upper part of the preliminary protective layer 150P so that the plurality of first through electrodes 130 are exposed. For example, the first protective layer 150 may be formed by removing a part of the preliminary lower protective layer 152P, a part of the preliminary intermediate protective layer 154P, and a part of the preliminary upper protective layer 156P at vertical levels higher than the top surfaces of the plurality of first through electrodes 130. In some embodiments, the first protective layer 150 may be formed by performing a chemical mechanical polishing (CMP) process to remove the upper part of the preliminary protective layer 150P. The first protective layer 150 may be on sidewalls of (e.g., to surround) the upper parts of the plurality of first through electrodes 130. For example, the first protective layer 150 may be formed by removing the upper part of the preliminary protective layer 150P such that the top end of the first lower protective layer 152, the top end of the first intermediate protective layer 154, the top surface of the first upper protective layer 156, and the top surfaces of the plurality of first through electrodes 130 may be coplanar at the same vertical level.

Referring to FIG. 4E, a first mask layer MK1 having at least one first mask opening MKO1 is formed on the first protective layer 150. For example, the first mask layer MK1 may include photoresist. The at least one first mask opening MKO1 may be formed at a position corresponding to the support structure 160-1, 160-2, or 160-3 illustrated in FIGS. 2A to 2C.

Referring to FIGS. 4E and 4F, after forming a preliminary support layer filling at least a part of the at least one first mask opening MKO1 and covering the first mask layer MK1, a lift-off process of removing the first mask layer MK1 is performed to form the support structure 160. In some embodiments, the preliminary support layer may fill a lower part of the at least one first mask opening MKO1 and may cover a top surface of the first mask layer MK1. The preliminary support layer may include the same material as the first upper protective layer 156.

Referring to FIG. 4G, a second mask layer MK2 having a plurality of second mask openings MKO2 is formed on the first protective layer 150. For example, the second mask layer MK2 may include photoresist. The plurality of second mask openings MKO2 may be formed at positions corresponding to the plurality of first through electrodes 130. In some embodiments, a horizontal width of each of the plurality of second mask openings MKO2 may be greater than that of each of the plurality of first through electrodes 130. For example, on bottoms of the plurality of second mask openings MKO2, parts of the top surfaces of the plurality of first through electrodes 130 and the top surface of the first protective layer 150 adjacent to the plurality of first through electrodes 130 may be exposed.

Referring to FIGS. 4G and 4H, after forming a preliminary pad layer filling at least parts of the plurality of second mask openings MKO2 and covering the second mask layer MK2, a lift-off process of removing the second mask layer MK2 is performed to form the first semiconductor chip 100 including the plurality of first rear connection pads 114. The plurality of first rear connection pads 114 may fill at least parts of the plurality of second mask openings MKO2 of the preliminary pad layer.

In some embodiments, the preliminary pad layer may fill lower parts of the plurality of second mask openings MKO2 and may cover a top surface of the second mask layer MK2. The preliminary pad layer may be formed by a plating process, such as electroplating or electroless plating. For example, the preliminary pad layer may include Cu.

The plurality of first rear connection pads 114 may be on the top surface of the first protective layer 150 and may cover the top surfaces of the plurality of first through electrodes 130. The plurality of first rear connection pads 114 may be connected to the plurality of first through electrodes 130, respectively.

The second protective layer 250 and the plurality of second rear connection pads 214 included in each of the plurality of second semiconductor chips 200 may be formed with reference to the method of manufacturing the first protective layer 150 and the plurality of first rear connection pads 114 described in FIGS. 4A to 4D and 4G and 4H. Each of the plurality of second semiconductor chips 200 may not include a configuration corresponding to the support structure 160 included in the first semiconductor chip 100.

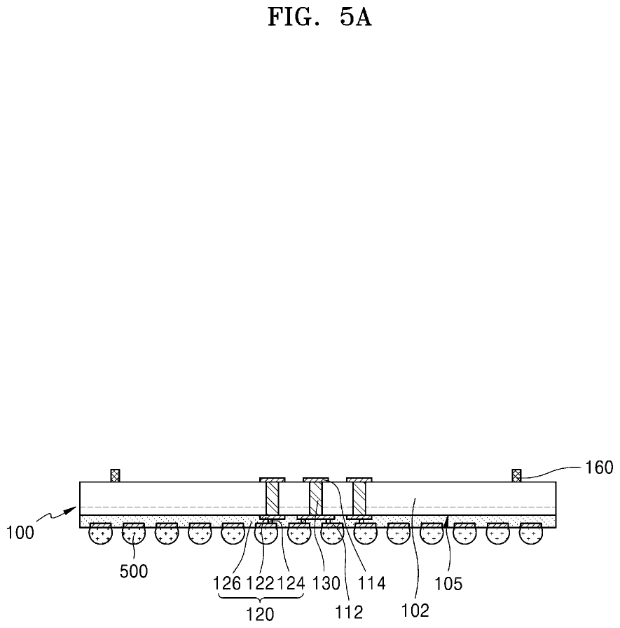

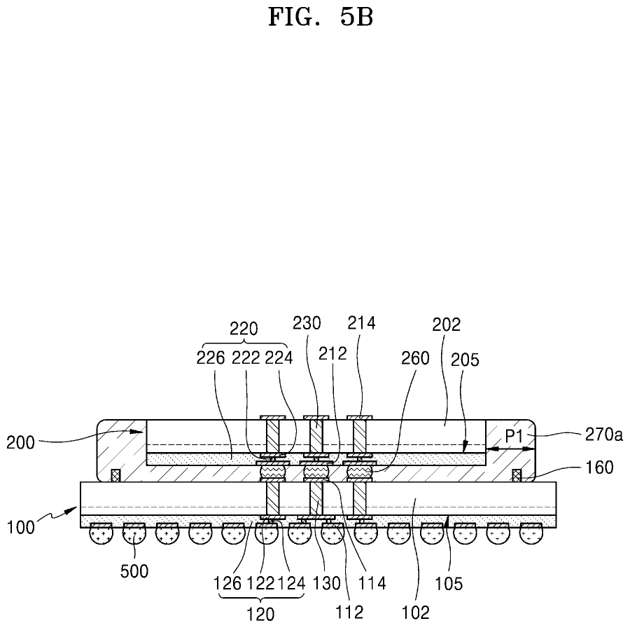

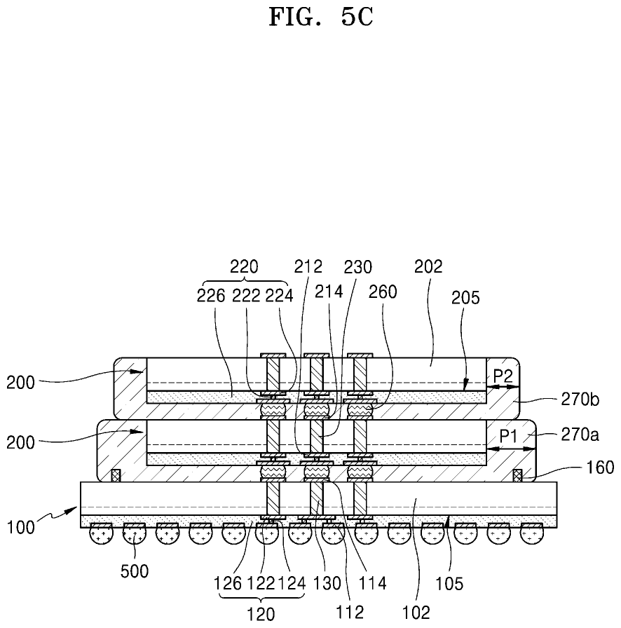

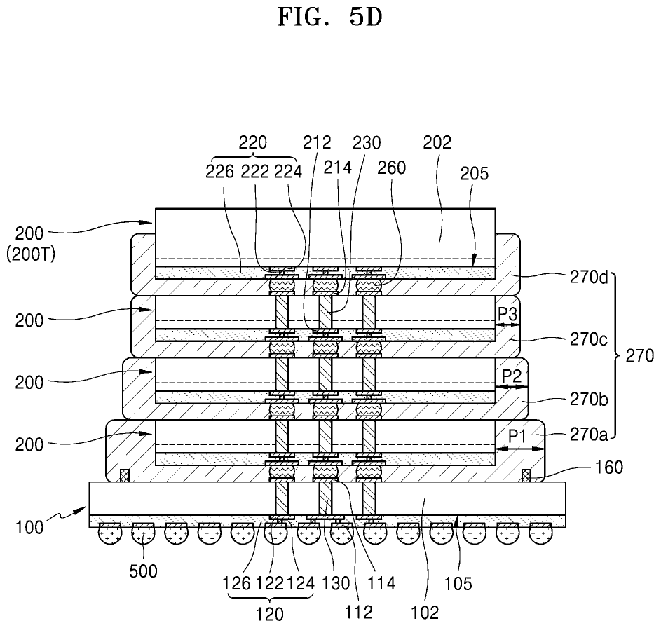

FIGS. 5A to 5D are cross-sectional views illustrating a method of manufacturing a semiconductor package according to an embodiment. Specifically, FIGS. 5A to 5D are cross-sectional views illustrating the method of manufacturing the semiconductor package 1 illustrated in FIGS. 1A and 1B, and in FIGS. 5A to 5D, the same reference numerals as in FIGS. 1A and 1B denote substantially the same members, and description previously given with reference to FIGS. 1A and 1B may be omitted.

Referring to FIG. 5A, the first semiconductor chip 100 is manufactured and prepared with reference to FIGS. 4A to 4H. The first semiconductor chip 100 includes the first substrate 102, the first semiconductor device 105, the first wiring layer 120, the plurality of first through electrodes 130, the first protective layer 150, the support structure 160, the plurality of first front connection pads 112, and the plurality of first rear connection pads 114. The plurality of package connection terminals 500 may be attached to the plurality of first front connection pads 112.

Referring to FIG. 5B, the second semiconductor chip 200, to a bottom surface of which the first insulating adhesive layer 270a is attached, is attached onto the first semiconductor chip 100. The second semiconductor chip 200 illustrated in FIG. 5B may be the lowermost second semiconductor chip 200 of the plurality of second semiconductor chips 200 illustrated in FIG. 1A. The second semiconductor chip 200, to the bottom surface of which the first insulating adhesive layer 270a is attached, may be attached onto the first semiconductor chip 100 by a thermal compression bonding process. By the thermal compression bonding process, a part of the first insulating adhesive layer 270a may protrude outward from between the top surface of the first semiconductor chip 100 and the bottom surface of the second semiconductor chip 200 to cover a part of the top surface of the first semiconductor chip 100, which is positioned outside between the top surface of the first semiconductor chip 100 and the bottom surface of the second semiconductor chip 200. The first insulating adhesive layer 270a may protrude from between the top surface of the first semiconductor chip 100 and the bottom surface of the second semiconductor chip 200 to further extend outward from the edge of the second semiconductor chip 200 in the horizontal direction to have the first protrusion length P1.

In some embodiments, the first insulating adhesive layer 270a may cover at least parts of the side surfaces of the second semiconductor chip 200. It is illustrated in FIG. 5B that the first insulating adhesive layer 270a covers all the side surfaces of the second semiconductor chip 200. However, the inventive concept is not limited thereto. In some embodiments, the first insulating adhesive layer 270a may cover only lower parts of the side surfaces of the second semiconductor chip 200.

The first insulating adhesive layer 270a may cover the support structure 160. For example, the first insulating adhesive layer 270a may cover the top and side surfaces of the support structure 160. The first insulating adhesive layer 270a may protrude further outward from the second semiconductor chip 200 than the support structure 160. For example, the edge of the first insulating adhesive layer 270a may be farther from the second semiconductor chip 200 than the support structure 160.

Referring to FIG. 5C, the second semiconductor chip 200, to a bottom surface of which the second insulating adhesive layer 270b is attached, is attached onto the lowermost second semiconductor chip 200. The second semiconductor chip 200 attached onto the lowermost second semiconductor chip 200 illustrated in FIG. 5C may be the lowermost second semiconductor chip 200 of the plurality of second semiconductor chips 280 illustrated in FIG. 1A. The second semiconductor chip 200, to the bottom surface of which the second insulating adhesive layer 270b is attached, may be attached onto the lowermost second semiconductor chip 200 by a thermal compression bonding process. A part of the second insulating adhesive layer 270b may move outward from between the two second semiconductor chips 200 by the thermal compression bonding process to cover a part of the top surface of the first insulating adhesive layer 270a. The second insulating adhesive layer 270b may protrude from between the top surface of the lowermost second semiconductor chip 200 to a bottom surface of the second semiconductor chip 200 to further extend outward from the edge of the second semiconductor chip 200 in the horizontal direction to have the second protrusion length P2. The second protrusion length P2 may be less than the first protrusion length P1.

Referring to FIG. 5D, the second semiconductor chips 200, to bottom surfaces of which the third insulating adhesive layer 270c and the fourth insulating adhesive layer 270d are attached, are sequentially attached onto the second semiconductor chip 200 attached onto the first semiconductor chip 100 by a thermal compression bonding process.

Then, the molding layer 400 illustrated in FIG. 1 on or surrounding the plurality of second semiconductor chips 200 and the plurality of insulating adhesive layers 270 may be formed on the first semiconductor chip 100 to form the semiconductor package 1. In some embodiments, unlike in FIG. 5A, the plurality of package connection terminals 500 may be attached to the plurality of first front connection pads 112 after forming the molding layer 400.

In the method of manufacturing the semiconductor package 1 according to the inventive concept, because the first insulating adhesive layer 270a exposed to a relatively high thermal compression environment covers the support structure 160, although the crack in which the first insulating adhesive layer 270a is separated from the first semiconductor chip 100 occurs at the edge of the first insulating adhesive layer 270a, the crack may not progress inward due to the support structure 160 so that structural reliability of the semiconductor package 1 may be secured and the electrical connection reliability between the first semiconductor chip 100 and the plurality of second semiconductor chips 200 may be secured.

While the inventive concept has been shown and described with reference to embodiments thereof, it will be understood that various changes in form and details may be made therein without departing from the spirit and scope of the following claims.

1. A semiconductor package comprising:
a first semiconductor chip including a support structure extending away from a upper major surface thereof;
a second semiconductor chip on the first semiconductor chip and having a horizontal width that is less than that of the first semiconductor chip and an edge horizontally apart from an edge of the first semiconductor chip; and
an insulating adhesive layer between the first semiconductor chip and the second semiconductor chip and extending away horizontally outward from between the first semiconductor chip and the second semiconductor chip and on the support structure, wherein the support structure is horizontally spaced apart from the edge of the second semiconductor chip and an edge of the insulating adhesive layer.

2. The semiconductor package of claim 1, wherein the insulating adhesive layer covers top and side surfaces of the support structure.

3. The semiconductor package of claim 1, wherein a vertical level of the top surface of the support structure is lower than that of a top surface of the second semiconductor chip.

4. The semiconductor package of claim 1, wherein a vertical level of the top surface of the support structure is lower than that of a bottom surface of the second semiconductor chip.

5. The semiconductor package of claim 1, wherein the first semiconductor chip comprises a first substrate having a first active surface and an opposing first inactive surface, a first protective layer on the first inactive surface of the first substrate, and a first wiring layer on the first active surface of the first substrate, wherein the second semiconductor chip comprises a second substrate having a second active surface facing the first inactive surface of the first substrate and a second inactive surface opposite to the second active surface, a second protective layer on the second inactive surface of the second substrate, and a second wiring layer on the second active surface of the second substrate, and
wherein the support structure is on the first protective layer.

6. The semiconductor package of claim 5, wherein the first protective layer comprises a first lower protective layer on a top surface of the first substrate, a first intermediate protective layer sequentially stacked on a top surface of the first lower protective layer and including a material different from the first lower protective layer, and a first upper protective layer sequentially stacked on a top surface of the first intermediate protective layer and including a material different from the first intermediate protective layer, and
wherein the support structure includes a same material as the first upper protective layer.

7. The semiconductor package of claim 1, wherein the support structure is horizontally spaced apart from the edge of the second semiconductor chip by a first distance and horizontally spaced apart from the edge of the insulating adhesive layer by a second distance less than the first distance.

8. A semiconductor package comprising:
a first semiconductor chip including a support structure extending away from an upper major surface thereof;
a plurality of second semiconductor chips sequentially stacked on the first semiconductor chip, each having a horizontal width that is less than that of the first semiconductor chip, and each having an edge horizontally spaced apart from an edge of the first semiconductor chip; and
a plurality of insulating adhesive layers between the first semiconductor chip and the plurality of second semiconductor chips and that extend away from between the first semiconductor chip and the plurality of second semiconductor chips, wherein the plurality of insulating adhesive layers comprise a first insulating adhesive layer between a lowermost second semiconductor chip of the plurality of second semiconductor chips and the first semiconductor chip and at least one second insulating adhesive layer between the plurality of second semiconductor chips, and
wherein the first insulating adhesive layer is on top and side surfaces of the support structure and extends horizontally further outward from between the lowermost second semiconductor chip of the plurality of second semiconductor chips and the first semiconductor chip than the support structure.

9. The semiconductor package of claim 8, wherein the support structure is horizontally spaced apart from the edge of the lowermost second semiconductor chip and the edge of a lowermost insulating adhesive layer.

10. The semiconductor package of claim 9, wherein the support structure is horizontally spaced apart from edges of the plurality of second semiconductor chips by a first distance, is horizontally spaced apart from an edge of the first insulating adhesive layer by a second distance less than the first distance, and extends along the edge of the first semiconductor chip and the edges of the plurality of second semiconductor chips.

11. The semiconductor package of claim 10, wherein a plurality of support structures correspond to the edges of the first semiconductor chip and the plurality of second semiconductor chips and are horizontally spaced apart from one another.

12. The semiconductor package of claim 10, wherein the support structure extends around a perimeter of the first semiconductor chip and the plurality of second semiconductor chips.

13. The semiconductor package of claim 8, wherein the first semiconductor chip comprises a first substrate having a first active surface and a first inactive surface opposite to each other, a plurality of first through electrodes extending onto the first inactive surface through at least a part of the first substrate, a first protective layer on the first inactive surface of the first substrate and on sidewalls of the plurality of first through electrodes, and a first wiring layer on the first active surface of the first substrate, wherein each of the plurality of second semiconductor chips comprises a second substrate having a second active surface facing the first inactive surface of the first substrate and a second inactive surface opposite to the second active surface, a second protective layer on the second inactive surface of the second substrate, and a second wiring layer on the second active surface of the second substrate, wherein the support structure is on a portion of the first protective layer that does not overlap the plurality of second semiconductor chips in a vertical direction, and
wherein the first insulating adhesive layer extends outward from between the lowermost second semiconductor chip of the plurality of second semiconductor chips and the first semiconductor chip on a portion of the first wiring layer that does not overlap the plurality of second semiconductor chips in a vertical direction and on the support structure.

14. The semiconductor package of claim 13, wherein the first protective layer comprises a first lower protective layer, a first intermediate protective layer, and a first upper protective layer sequentially stacked on a top surface of the first substrate, and
wherein the first upper protective layer and the first insulating adhesive layer extend around the support structure.

15. The semiconductor package of claim 14, wherein the first upper protective layer and the support structure include the same material.

16. The semiconductor package of claim 14, wherein a top end of the first lower protective layer, a top end of the first intermediate protective layer, a top surface of the first upper protective layer, and top surfaces of the plurality of first through electrodes are coplanar at a same vertical level.

17. The semiconductor package of claim 14, wherein a height of the support structure is less than a vertical distance between the lowermost second semiconductor chip of the plurality of second semiconductor chips and the first semiconductor chip.

18. The semiconductor package of claim 14, wherein a length of the first insulating adhesive layer that extends horizontally outward from between the first semiconductor chip and the plurality of second semiconductor chips is greater than that of the at least one second insulating adhesive layer.

19. A semiconductor package comprising:
a buffer chip including a first substrate having a first active surface and an opposite first inactive surface, a plurality of first through electrodes extending onto the first inactive surface through at least a part of the first substrate, a first protective layer including a first lower protective layer, a first intermediate protective layer, and a first upper protective layer on the first inactive surface of the first substrate and on sidewalls of the plurality of first through electrodes, a support structure extending away from a top surface of the first upper protective layer and including the same material as the first upper protective layer, and a first wiring layer on the first active surface of the first substrate;
a plurality of memory cell chips each having a width less than that of the buffer chip, the plurality of memory cell chips being sequentially stacked on the buffer chip, and including a second substrate having a second active surface facing the first inactive surface of the first substrate and an opposite second inactive surface, a second protective layer on the second inactive surface of the second substrate, and a second wiring layer on the second active surface of the second substrate;
a plurality of chip connection terminals between the buffer chip and the plurality of memory cell chips;
a plurality of insulating adhesive layers between the buffer chip and the plurality of memory cell chips and on sidewalls of the plurality of chip connection terminals, wherein the plurality of insulating adhesive layers extend away from between the buffer chip and the plurality of memory cell chips; and
a molding layer on the plurality of memory cell chips and the plurality of insulating adhesive layers on the buffer chip, wherein the plurality of insulating adhesive layers comprise a first insulating adhesive layer between a lowermost memory cell chip of the plurality of memory cell chips and the buffer chip and at least one second insulating adhesive layer between the plurality of memory cell chips, wherein the first insulating adhesive layer extends further outward from between the lowermost memory cell chip of the plurality of memory cell chips and the buffer chip than the support structure on top and side surfaces of the support structure, and
wherein a vertical level of the top surface of the support structure is lower than that of a bottom surface of the lowermost memory cell chip of the plurality of memory cell chips.

20. The semiconductor package of claim 19, wherein each of a height and a width of the support structure is about 3 μm to about 15 μm.

21-30. (canceled)
